(19) United States
(12) Patent Application Publication
(10) Pub. No.: US 2008/0224287 A1
(43) Pub. Date: Sep. 18, 2008

(54) OPTOELECTRONIC DEVICE ALIGNMENT IN AN OPTOELECTRONIC PACKAGE

(75) Inventors: Jose J. Aizpuru, Murphy, TX (US); Harold Y. Walker, Murphy, TX (US)

Correspondence Address: WORKMAN NYDEGGER, 60 EAST SOUTH TEMPLE, 1000 EAGLE GATE TOWER, SALT LAKE CITY, UT, 84111, US

(73) Assignee: FINISAR CORPORATION, Sunnyvale, CA (US)

(21) Appl. No.: 11/687,380

(22) Filed: Mar. 16, 2007

(51) Int. Cl. H01L 23/495

(52) U.S. Cl. 257/676; 257/E23.039

(57) ABSTRACT

Using one or more reference indicators in die attaching an optoelectronic device to a lead during the assembly of an optoelectronic package. One example method of assembling an optoelectronic package includes detecting a reference indicator included in a first component of an optoelectronic package. The method also includes die attaching a second component to the optoelectronic package at a die attach location. The die attach location is substantially aligned with the reference indicator along a line that intersects the reference indicator and is parallel to either an x-axis or a y-axis of an x-y coordinate system associated with the optoelectronic package.

### BACKGROUND

1. The Field of the Invention

The present invention relates generally to the assembly of an optoelectronic package. More particularly, example embodiments of the invention concern the use of one or more reference indicators in die attaching an optoelectronic device to a lead during the assembly of an optoelectronic package so that the optoelectronic device is substantially aligned with one or more other components of the optoelectronic package, such as an optical window.

2. Related Technology

Optoelectronic packages are used in the field of fiber-optic communication to convert optical data signals to electrical data signals and/or to convert electrical data signals to optical data signals. This conversion is achieved in an optoelectronic package generally by an optoelectronic device. An optoelectronic device is an electrical-to-optical or optical-to-electrical transducer. Examples of optoelectronic devices include, but are not limited to, light emitting diodes (“LEDs”), laser diodes (“LDs”), vertical cavity surface emitting lasers (“VCSELs”), and photodiodes.

The optoelectronic device of an optoelectronic package can be die attached to a metal leadframe included in the optoelectronic package. Some metal leadframes include multiple conductive leads that are generally at least partially encased within an injection molded plastic casing. In addition to the optoelectronic device, other electrical components are also generally encased within the casing and electrically connected to the leads of the leadframe. The casing provides electrical insulation for the leads and other electrical components of the optoelectronic package, as well as mechanical support for the leads. A portion of each lead that extends outside the casing can be electrically connected to, for example, a printed circuit board. The leads of an optoelectronic package can, therefore, enable power and electrical signals to be transmitted between electrical components encased within the casing of the optoelectronic package and electrical components that are outside the casing of the optoelectronic package.

Where an optoelectronic package includes an optoelectronic device die attached to a lead within the casing of the optoelectronic package, the casing will typically also include an optical window. The optical window serves as an optical interface to a fiber-optic cable by enabling optical data signals to be transmitted between the optoelectronic device and a fiber-optic cable. For example, the optical window can be positioned within an optical port. The optical port can be configured to receive a fiber-optic ferrule that is attached to a corresponding fiber-optic cable. The connection of a fiber-optic ferrule to the optical port can enable the transmission of optical signals between the corresponding fiber-optic cable and the optoelectronic package. Because optical signals must pass between the optoelectronic device and a fiber-optic cable by way of the optical window, the alignment of the optoelectronic device with respect to the optical window must be such that the optical signals passing through the optical window are not materially compromised.

In order to properly align the optoelectronic device with the optical window, the optoelectronic device must be die attached to a specific die attach location on a lead within the optoelectronic package. The die attach location is generally associated with very tight tolerances.

In one assembly process, the die attachment location of an optoelectronic device on a lead within an optoelectronic package is located using edges of the lead as lines of reference.

The use of lead edges to locate a die attach location can be problematic, however. For example, lead edges often suffer from manufacturing imperfections that impair their effectiveness as reference lines. For example, leads are often produced using a less-costly etching method during the design phase and a more-costly stamping method during the production phase. The etching method can result in leads with somewhat rough, non-linear, or undefined edges. As a result, the frame of reference provided by the lead edges is not clear and the tight tolerances for the die attach location for an optoelectronic device may not be achieved, or not easily achieved.

Another problem with using lead edges as lines of reference in locating a die attach location is that corners or curves of a lead edge can tend to run together. When corners or curves on a lead edge run together, it can be difficult to discern a straight edge upon which to base a die attach location. Another problem with using lead edges as lines of reference in locating a die attach location is that a lead edge may be relatively distant from the die attach location, which can necessitate viewing the lead edges at a relatively low magnification resulting in a corresponding low level of accuracy in locating the die attach location. Alternating between a low level of magnification to a high level of magnification in order to improve accuracy can necessitate extra production steps to positively identify the die attach location.

### BRIEF SUMMARY OF SOME EXAMPLE EMBODIMENTS

In general, example embodiments of the invention relate to the use of one or more reference indicators in die attaching an optoelectronic device to a lead during the assembly of an optoelectronic package so that the optoelectronic device is substantially aligned with one or more other components of the optoelectronic package, such as an optical window.

In one example embodiment, an optoelectronic package includes a leadframe and a first component. The leadframe includes a plurality of metal leads. The first component is die attached to one of the metal leads at a die attach location.

The optoelectronic package also includes a reference indicator included either in one of the metal leads or in a casing of the optoelectronic package. The optoelectronic device is substantially aligned with the reference indicator along a line that intersects the reference indicator and is parallel to either an x-axis or a y-axis of an x-y coordinate system associated with the optoelectronic package.

In another example embodiment, an assembly method is disclosed. The assembly method includes detecting a reference indicator included in a first component of an optoelectronic package. The method also includes die attaching a second component to the optoelectronic package at a die attach location. The die attach location is substantially aligned with the reference indicator along a line that intersects the reference indicator and is parallel to either an x-axis or a y-axis of an x-y coordinate system associated with the optoelectronic package.

These and other aspects of example embodiments of the present invention will become more fully apparent from the following description and appended claims.

### BRIEF DESCRIPTION OF THE DRAWINGS

To further clarify the above and other aspects of the present invention, a more particular description of these examples will be rendered by reference to specific embodiments thereof which are disclosed in the appended drawings. It is appreciated that these drawings depict only example embodiments of the invention and are therefore not to be considered limiting of its scope. It is also appreciated that the drawings are diagrammatic and schematic representations of exemplary embodiments of the invention, and are not limiting of the present invention nor are they necessarily drawn to scale. Example embodiments of the invention will be disclosed and explained with additional specificity and detail through the use of the accompanying drawings in which:

FIG. 1 discloses an example fiber-optic network environment;

FIGS. 2A-2E disclose an example optoelectronic package having reference indicators associated with a portion of the optoelectronic package;

FIGS. 3A-3C disclose another example optoelectronic package having reference indicators associated with a portion of the optoelectronic package; and

FIG. 4 discloses an example method for assembling an optoelectronic package using one or more reference indicators.

### DETAILED DESCRIPTION OF SOME EXAMPLE EMBODIMENTS

As noted above, example embodiments of the invention relate to the use of one or more reference indicators in die attaching an optoelectronic device to a lead during the assembly of an optoelectronic package so that the optoelectronic device is substantially aligned with one or more other components of the optoelectronic package, such as an optical window. The term “reference indicator” as used herein refers to a marking, indentation, hole, or other visible indicator that can be used as a point of reference in an automated assembly process to facilitate die attachment of a first component to a second component of an optoelectronic package. A reference indicator can be formed, for example, by punching or etching. The term “die attaching” as used herein refers to the process of attaching a first component onto some type of packaging component or carrier. For example, the term “die attaching” can refer to the process of attaching an optoelectronic device onto a lead of a leadframe of an optoelectronic package.

The reference indicator(s) are used by a camera in one example of an automated assembly process. Specifically, the camera uses each reference indicator as a point of reference to pinpoint the “x-coordinate” and/or the “y-coordinate” of a die attach location on a lead within the optoelectronic package. The term “die attach location” as used herein refers to the location at which an optically operative portion of an first component must be positioned in order to properly align the first component with one or more other components of an optoelectronic package. For example, a “die attach location” for an optoelectronic device is the location at which an optically operative portion of the optoelectronic device must be positioned in order to properly align the optoelectronic device with one or more other components of an optoelectronic package such as, for example, an optical window of the optoelectronic package. Where the optoelectronic device is an optical transmitter, for example, the optically operative portion of the transmitter is the transmission area of the transmitter. In another example where the optoelectronic device is an optical receiver, the optically operative portion of the receiver is the reception area of the receiver.

The use of reference indicators can enhance the functionality of a camera in an automated assembly process. For example, where one or more reference indicators are used in the assembly process of an optoelectronic package, the reference indicators can be used as points of reference for the attachment locations of other components of the optoelectronic package. For example, the one or more reference indicators can be formed or included in the initial phases of the assembly process. Thereafter, the one or more reference indicators can be used, for example, to locate the location of leads, the location of an optoelectronic device, and/or the location of a casing that includes an optical window. The reference indicator(s) can therefore be used to facilitate the alignment of the optical window with the optoelectronic device.

In one example automated assembly process, the placement of reference indicators relatively near the desired location of the optoelectronic device also enables the camera to focus simultaneously on both the reference indicators and the die attach location with the camera at maximum magnification. This avoids any undesirable misfocusing of the camera in the x-direction or the y-direction that may inadvertently be caused by changing the magnification of the camera in order to refocus the camera on the die attach location at a less-than-maximum level of magnification.

A proper alignment between the optoelectronic device and one or more other components of an optoelectronic package can be achieved in the example optoelectronic packages disclosed herein due to the ability to locate the die attach location using one or more reference indicators as points of reference.

### I. Example Fiber-Optic Network Environment

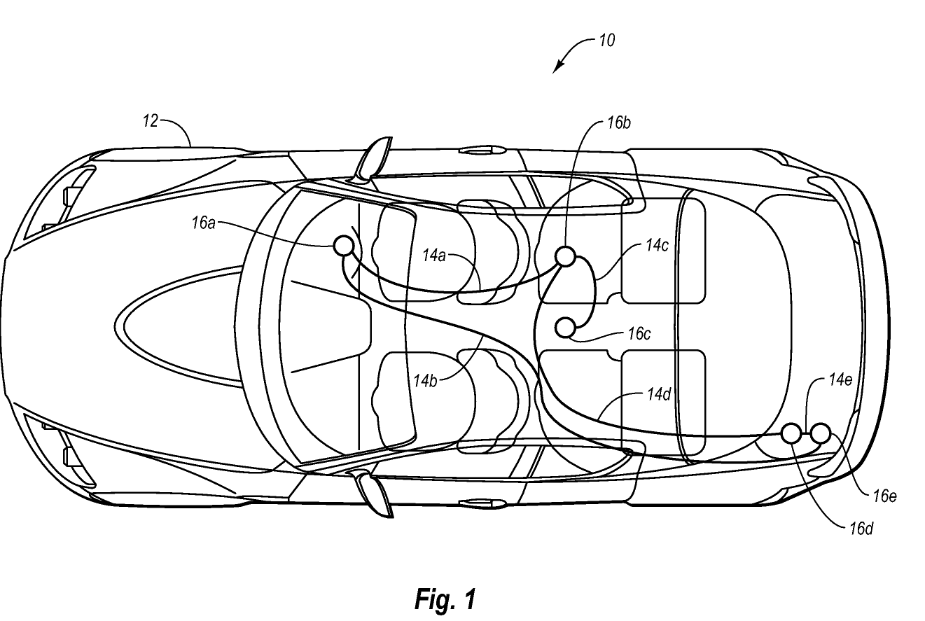

With reference now to FIG. 1, an example fiber-optic network 10 is disclosed. The example fiber-optic network 10 is integrated into an automobile 12. The automobile 12 disclosed in FIG. 1 is only one example of an automobile into which the example fiber-optic network 10 can be integrated, and any other types and configurations of automobiles into which the example fiber-optic network 10 can be integrated are contemplated as within the scope of the present invention. In addition, the scope of the invention is not limited to automobile applications, and extends to all fiber-optic networks.

Automobiles have evolved from having a simple radio with perhaps a cassette or CD player to having a variety of sophisticated information systems that can benefit from being capable of communicating and interacting with each other and with a human user. For example, automobiles can include GPS navigation systems that can work in conjunction with a security system to locate a stolen car. Also, an automobile telephone may need to interact with the stereo system to mute the stereo system when a call is requested or received. Voice control and hands-free speakerphones may require a microphone to digitize the voice. Display systems may be used for navigation information and DVD playback.

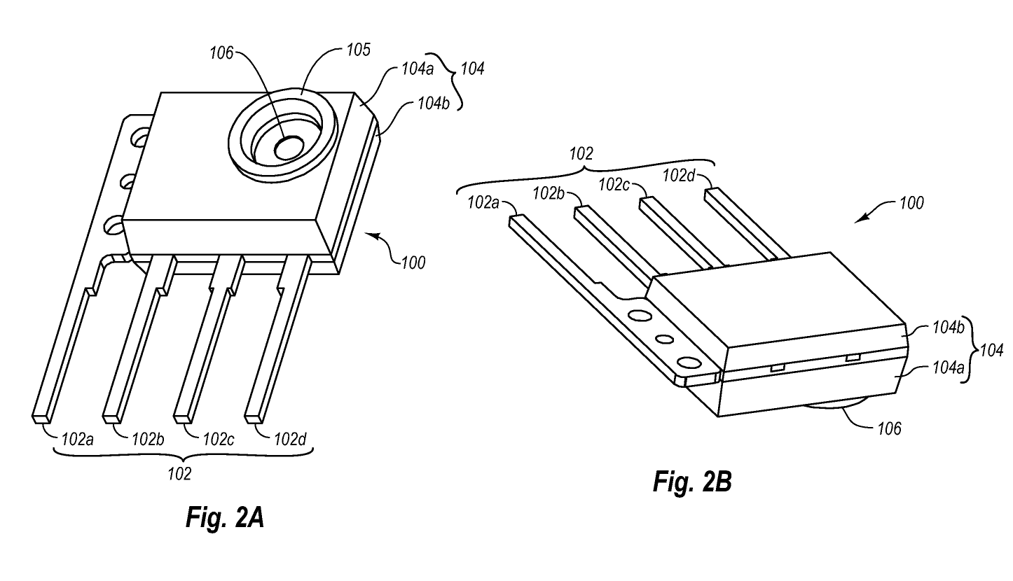

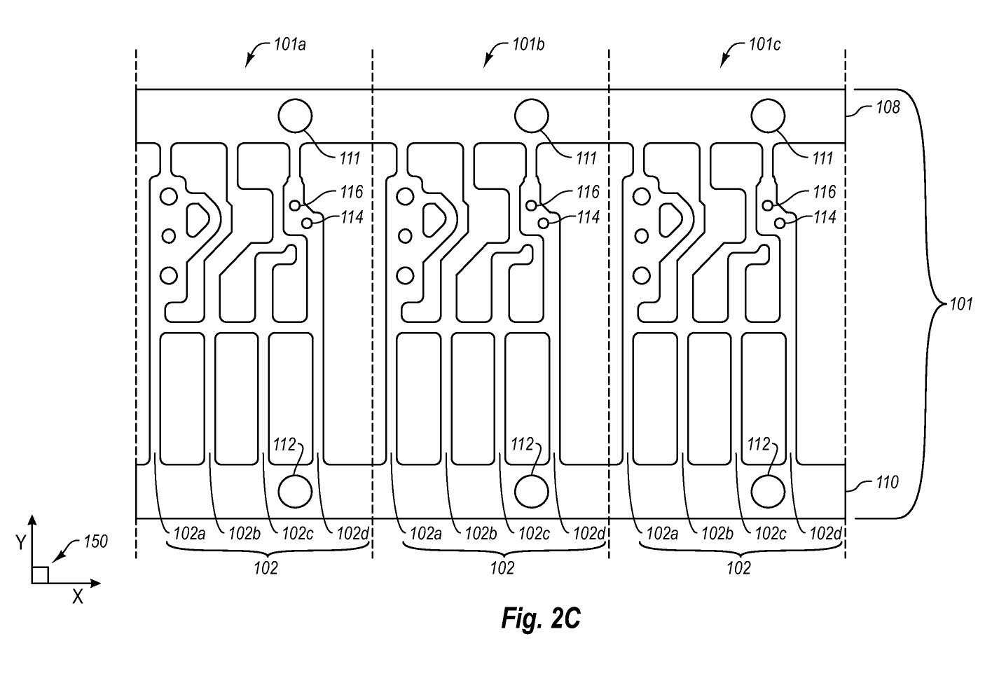

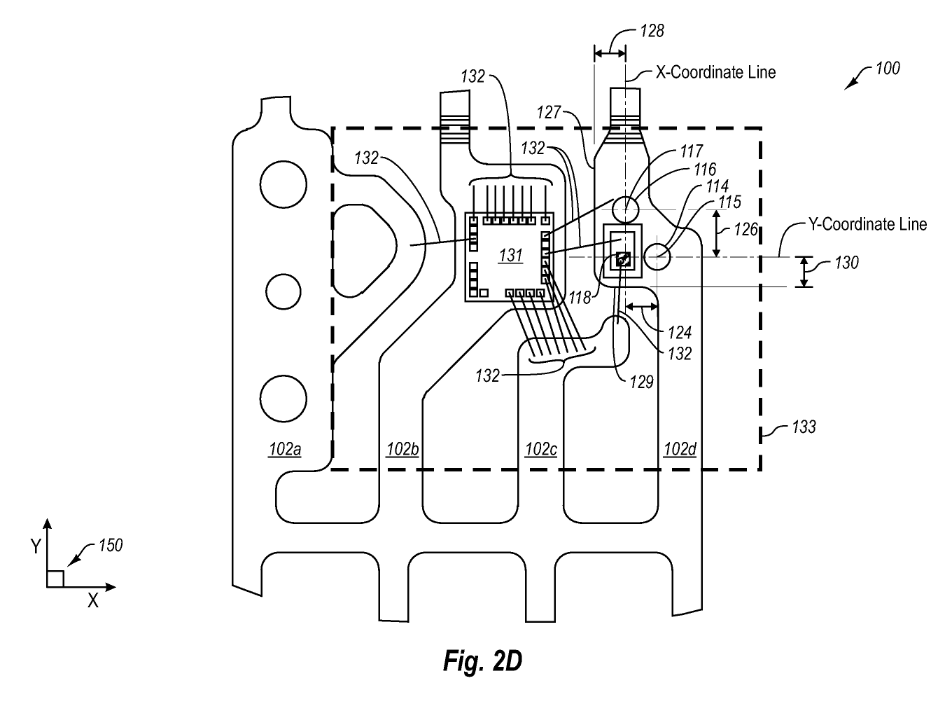

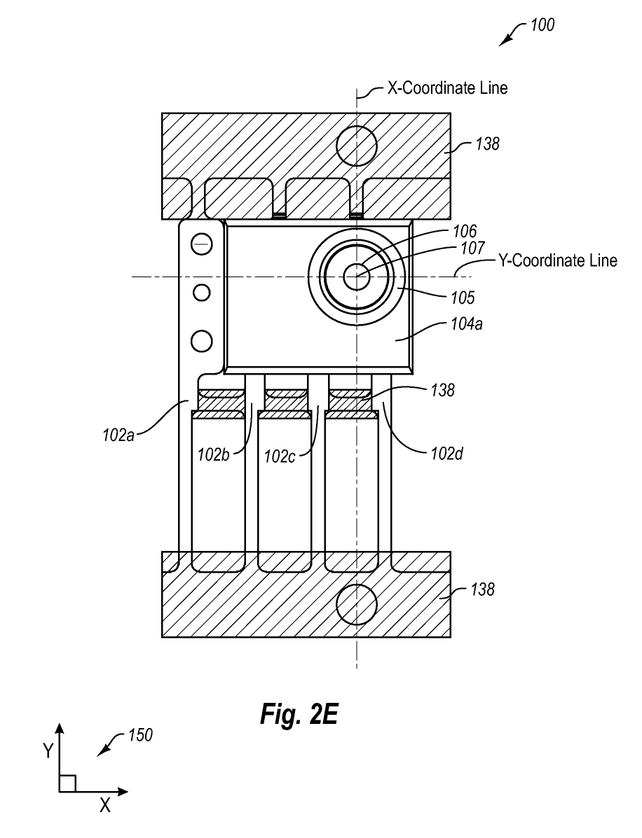

The example fiber-optic network 10 includes fiber-optic cabling 14a-14e that interconnects various network components 16a-16e. For example, a system control unit 16a is connected to fiber-optic cabling 14a and 14b, a first display unit 16b is connected to fiber-optic cabling 14a, 14c and 14d, a second display unit 16c is connected to fiber-optic cabling 14c, a multi-disc compact disc player 16d is connected to fiber-optic cabling 14d and 14e, and an amplifier 16e is connected to fiber-optic cabling 14b and 14e. In order for the various network components 16a-16e to communicate over the fiber-optic cabling 14a-14e, electrical data signals must be converted to optical data signals and vice-versa. This conversion between optical and electrical data signals requires the use an optoelectronic package configured as a transmitter optical sub-assembly (“TOSA”) and/or a receiver optical sub-assembly (“ROSA”). The structure and assembly of example optoelectronic packages suitable for integration into the various network components 16a-16e of the fiber-optic network 10 are disclosed below in connection with FIGS. 2A-4.

### II. Example Reference Indicators in an Optoelectronic Package

With reference now to FIGS. 2A-2B, an example optoelectronic package 100 is disclosed. The example optoelectronic package 100 can include an optical transmitter, such as a laser for example, and be configured as a TOSA. Alternatively, the example optoelectronic package 100 can include an optical receiver, such as a photo diode for example, and be configured as a ROSA.

With continuing reference to FIGS. 2A and 2B, the optoelectronic package 100 includes a leadframe 102 that includes a plurality of leads 102a-102d extending outward from a casing 104. The casing 104 can be formed from any suitable insulating or dielectric material, such as injection molded plastic for example. The casing 104 includes a first portion 104a positioned on one side of the leadframe 102 and a second portion 104b generally positioned on another side of the leadframe 102, although these two portions can be molded as a single integral casing. Among other things, the casing 104 provides mechanical support to the leadframe 102. The casing 104 also provides electrical isolation for the portions of the leadframe 102 encased within the casing 104.

The optoelectronic package 100 also includes an optical window 106 included in the first portion 104a of the casing 104. The optical window 106 is an open aperture that enables direct optical access to internal components of the optoelectronic package 100. In one alternative embodiment, an optical lens may be positioned in the optical window 106 in order to focus or collimate optical signals passing through the optical window 106. An optical lens could also protect internal components of the optoelectronic package 100 from dust and other particles, as well as seal the interior of the optoelectronic package 100.

The optical window 106 is positioned within an optical port 105. The optical port 105 is sized and configured to receive an optical connector, such as a fiber-optic ferrule, for example (not shown). When an optical connector attached to a corresponding fiber-optic cable is connected to the optical port 105, the optical window 106 enables optical signals to pass between the optoelectronic package 100 and the fiber-optic cable.

For example, where the optoelectronic package 100 includes an optical transmitter, optical signals generated by the optical transmitter can pass from the optoelectronic package 100 through the optical window 106 and into the fiber-optic cable. Alternatively, where the optoelectronic package 100 includes an optical receiver, optical signals generated by a distant optical transmitter can pass from the fiber-optic cable through the optical window 106 and into the optical receiver.

With reference now to FIGS. 2C-2E, details regarding some internal components of the example optoelectronic package 100 are disclosed. In particular, details are disclosed regarding the use of one or more reference indicators to locate the die attach location for an optoelectronic device within the optoelectronic package 100.

With particular reference first to FIG. 2C, an example tape 101 is disclosed. The tape 101 includes three example sections 101a-101c from which three separate leadframes 102 can be formed. An example of an optoelectronic package into which a leadframe 102 has been integrated was disclosed above in connection with FIGS. 2A and 2B. Each section 101a-101c of the tape 101 includes several components. These components include a leadframe 102 that includes a set of leads 102a-102d, a top rail 108, a bottom rail 110, a top guide hole 111, a bottom guide hole 112, a first reference indicator 114, and a second reference indicator 116. Each of these components is formed in the tape 101 through a process of, for example, stamping or etching, but other suitable processes could be used. Each of these components will now be disclosed in greater detail.

The rails 108 and 110 provide mechanical support for the leadframe 102 before the leadframe 102 is encased in the casing 104. The guide holes 111 and 112 of the rails 108 and 110 are used to enable the sections 101a-101c of the tape 101 to be fed through machinery associated with the assembly of each optoelectronic package 100. The size and substantially circular geometry of the guide holes 111 and 112 disclosed in FIG. 2C are example sizes and geometries, and could have various other shapes and sizes to better suit a particular manufacturing process.

FIG. 2C also discloses an x-y coordinate system 150. The x-axis and the y-axis of the x-y coordinate system 150 are substantially parallel to and perpendicular to, respectively, the rails 108 and 110. The orientation of the rails 108 and 110 can, therefore, be used to determine the orientation of the x-y coordinate system 150.

With continued reference to FIG. 2C and as noted above, each leadframe 102 includes a first reference indicator 114 and a second reference indicator 116 included in the lead 102d, although these reference indicators could be located elsewhere on the leadframe 102. As disclosed in FIG. 2C, each reference indicator 114 and 116 is a substantially circular hole formed in the lead 102d. This configuration of the reference indicator 114 and 116 can be desirable in some applications because as the instrument used to punch a substantially circular hole wears during use, the instrument will continue to punch a relatively circular hole, albeit gradually smaller in diameter. As disclosed elsewhere herein, however, in other applications each reference indicator 114 and 116 could be another type of hole, a marking, an indentation, or other visible indicator and could have a size and/or geometry different from the size and geometry disclosed in FIG. 2C.

Each reference indicator 114 and 116 is precisely positioned in the lead 102d in order to be used as a point of reference when locating a die attach location for an optoelectronic device or other component. In particular, the reference indicator 114 is precisely positioned so as to lie at a known coordinate on the x-coordinate line and the reference indicator 116 is precisely positioned so as to lie at a known coordinate on the y-coordinate line, as disclosed in FIG. 2D. The x-coordinate and y-coordinate lines pass through the die attach location of an optoelectronic device 118 disclosed in FIG. 2D. More particularly, as the leadframes 102 are formed in the tape 101, reference indicators 114 and 116 are formed to serve as points of reference for the die attach location of the optoelectronic device 118 disclosed in FIG. 2D, as well as to serve as common points of reference for the attachment location of the first portion 104a of the casing 104 disclosed in FIGS. 2A and 2B. By locating both the die attach location of the optoelectronic device 118 and the attachment location of the first portion 104a using the same reference indicators 114 and 116, an alignment between, for example, the optical window 106 of the first portion 104a and the optically operative portion of the optoelectronic device 118 can be achieved.

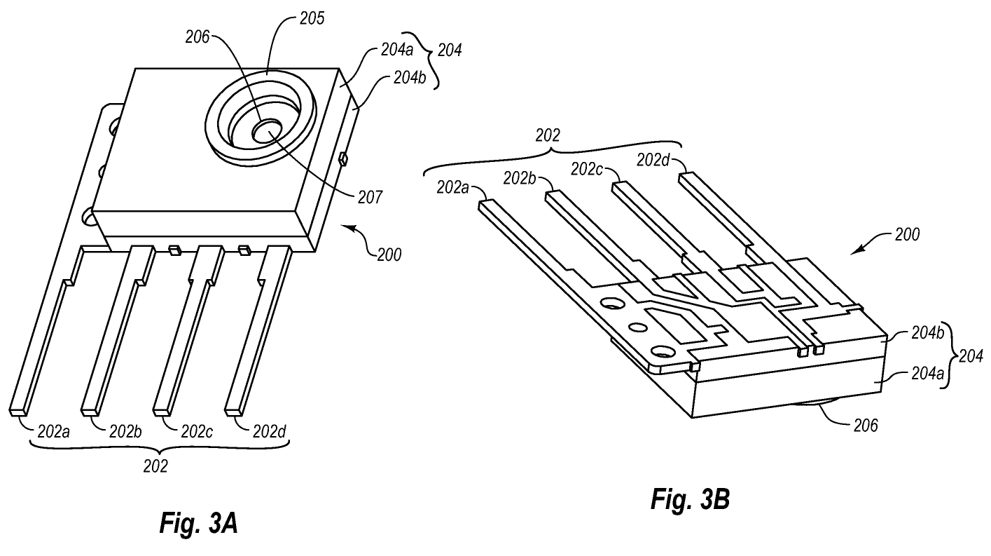

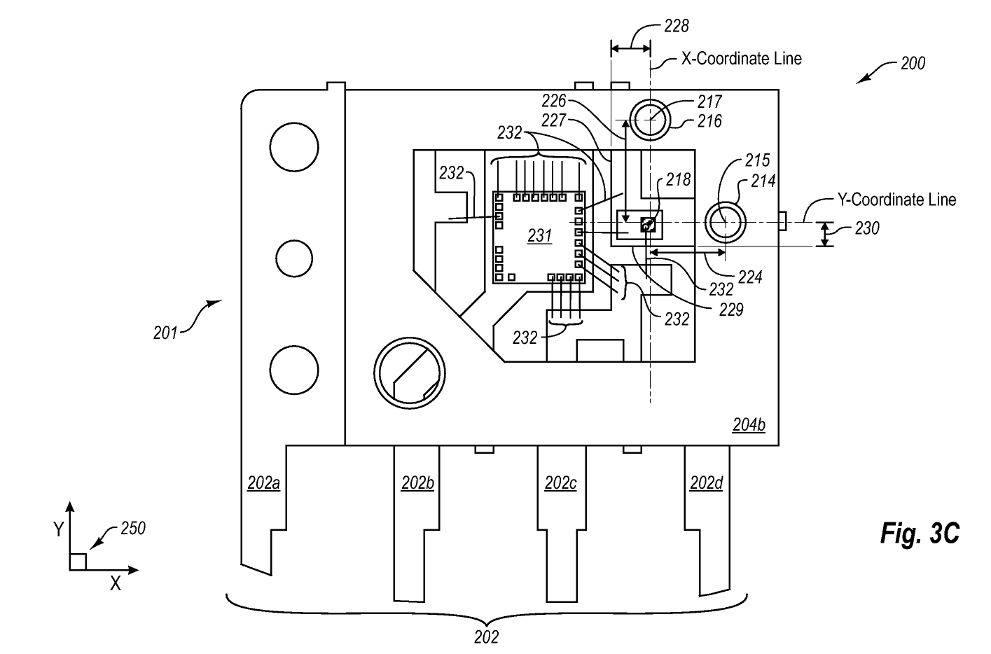

Although the reference indicators 114 and 116 disclosed in FIG. 2C are included in the same lead 102d to which the optoelectronic device 118 will be die attached, in other example optoelectronic packages, one or both of the reference indicators 114 and 116 may be included in a lead other than the lead to which the optoelectronic device 118 will be attached. Alternatively, one or both of the reference indicators 114 and 116 may be included in another component of the optoelectronic package other than the leads 102a-102d, an example of which is disclosed in greater detail below in connection with FIGS. 3A-3C.

With particular reference now to FIG. 2D, additional details regarding the reference indicators 114 and 116, and a die attach location of an optoelectronic device 118, are disclosed. In particular, FIG. 2D discloses details concerning how the reference indicators 114 and 116 can be used to locate the die attach location of the optoelectronic device 118 on the lead 102d. The optoelectronic device 118 can be, for example, a surface emitting laser, an edge emitting laser, a light emitting diode, a laser diode, or a photodetector.

The center 115 of the first reference indicator 114 and the center 117 of the second reference indicator 116 can be used to locate the die attach location of the optoelectronic device 118. In particular, the center 115 of the first reference indicator 114 can be used to locate a y-coordinate the die attach location of the optoelectronic device 118. The center 117 of the second reference indicator 116 can be used to locate an x-coordinate of the die attach location of the optoelectronic device 118. The x-coordinate and the y-coordinate correspond to the x-y coordinate system 150 disclosed in FIGS. 2C-2E.

In one alternative embodiment, a single reference indicator can be used to locate a die attach location for an optoelectronic device. For example, where the second reference indicator 116 is omitted from the lead 102d, the y-coordinate of the die attach location can be located using the center 115 of the first reference indicator 114, as disclosed above. The x-coordinate of the die attach location can then be located by measuring a predetermined distance 124 to the left of the center 115 along a line (the y-coordinate line) that intersects the center 115 and is parallel to the x-axis of the x-y coordinate system 150.

In another example, where the first reference indicator 114 is omitted from the lead 102d, the x-coordinate of the die attach location can be located using the center 117 of the second reference indicator 116, as discussed above. The y-coordinate of the die attach location can then be located by measuring a predetermined distance 126 down from the center 117 along a line (the x-coordinate line) that intersects the center 117 and is parallel to the y-axis of the x-y coordinate system 150.

In another alternative embodiment, a combination of a reference indicator and the edge of a lead can be used to locate a die attach location for an optoelectronic device. For example, where the second reference indicator 116 is omitted from the lead 102d, the y-coordinate of the die attach location can be located using the center 115 of the first reference indicator 114, as disclosed above, and the x-coordinate of the die attach location can then be located by identifying an edge 127 of the lead 102d and measuring a predetermined distance 128 to the right of the edge 127 along a line (the y-coordinate line) that intersects the center 115 and is parallel to the x-axis of the x-y coordinate system 150.

In another example, where the first reference indicator 114 is omitted from the lead 102d, the x-coordinate of the die attach location can be located using the center 117 of the second reference indicator 116, and the y-coordinate of the die attach location can then be located by identifying an edge 129 of the lead 102d and measuring a predetermined distance 130 up from the edge 129 along a line (the x-coordinate line) that intersects the center 117 and is parallel to the y-axis of the x-y coordinate system 150. These four examples illustrate the usefulness of even a single reference indicator in locating a die attach location for an optoelectronic device. Specifically, a single reference indicator, alone or in combination with the edge of a lead or other structural reference point, can be used to locate a die attach location for an optoelectronic device or anther component. Although embodiments including two or more reference indicators may be employed successfully in locating a die attach location in some embodiments, these four examples illustrate the usefulness of even a single reference indicator in locating a die attach location.

In addition, in another example embodiment, two or more reference indicators can be used to independently locate a die attach location on a leadframe without reference to the x-y coordinate system 150 disclosed in FIGS. 2C-2E. In this example embodiment, two reference indicators can be used to independently define a line. The independently defined line need not be parallel nor perpendicular to the rails 108 and 110 of the leadframe 102. For example, an embodiment including two pairs of reference indicators can be used to define two lines that intersect to pinpoint a die attach location. Therefore, example embodiments using two or more reference indicators to locate a die attach location independent from an x-y coordinate system are contemplated as within the scope of the present invention.

Once the die attach location of the optoelectronic device 118 is located, the optoelectronic device 118 is die attached to the lead 102d at the die attach location. This die attachment can be achieved, for example, by affixing the optoelectronic device 118 to the lead 102d using epoxy or other suitable adhesive.

With continuing reference to FIG. 2D, the optoelectronic package 100 also includes an integrated circuit 131. The integrated circuit 131 is attached to the lead 102b. This attachment of the integrated circuit 131 can be achieved, for example, by affixing the optoelectronic device 131 to the lead 102d using epoxy or other suitable adhesive. The integrated circuit 131 is also electrically connected to each of the leads 102a-102d and the optoelectronic device 118 via a plurality of wire bonds 132. The wire bonds 132 enable electrical communication between the integrated circuit 120 and each of the leads 102a-102d and the optoelectronic device 118. The integrated circuit 131 can be used, for example, to control the operation of the optoelectronic device 118.

After the optoelectronic device 118 is die attached to the lead 102d and the integrated circuit 131 is attached to the lead 102b, the casing 104 is attached to the leads 102a-102d. As noted earlier, the reference indicators 114 and 116 can serve as points of reference for locating the attachment location of the casing 104, and more particularly, the first portion 104a of the casing 104. By fixing both the die attach location of the optoelectronic device 118 and the location of the first portion 104a to the same reference indicators 114 and 116, an alignment between, for example, the optical window 106 and the optically operative portion of the optoelectronic device 118 can be achieved.

The attachment of the casing 104 can be achieved in a number of ways, including injection molding the casing 104 around the leadframe 102 or premolding the casing 104 and fastening the casing around the leadframe 102. FIG. 2D discloses an outline 132 of the approximate extent of the casing 104.

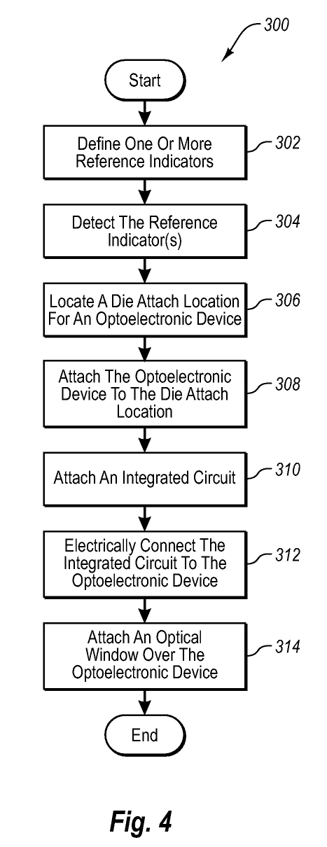

With particular reference now to FIG. 2E, the optoelectronic package 100 is disclosed with the casing 104 attached to the leadframe 102. In particular, FIG. 2E discloses the first portion 104a of the casing 104 attached to the leads 102a-102d. FIG. 2E also discloses the optical window 106 disposed over the top of the die attach location of the optoelectronic device 118 (disclosed in FIG. 2D). In particular, FIG. 2E discloses that the intersection of the x-coordinate line and the y-coordinate line substantially corresponds to the center 107 of the optical window 106. The optically operative portion of the optoelectronic device 118 is therefore substantially aligned with the optical window 106 such that optical signals can pass between the optoelectronic device 118 and any fiber-optic cable (not shown) that is connected to the optical port 105. FIG. 2E also discloses shaded areas 138 where the metal connecting the leads 102a-102d together, and the metal rails 108 and 110, are trimmed from the optoelectronic package 100 in order to electrically isolate each of the leads 102a-102d and give the optoelectronic package 100 the final form factor disclosed in FIGS. 2A and 2B. The automated assembly process used to assemble optoelectronic packages, such as the optoelectronic package 100, using one or more reference indicators will be disclosed in greater detail below in connection with the discussion of FIG. 4.

### III. Alternative Example Reference Indicators in an Optoelectronic Package

With reference now to FIGS. 3A-3C, another example optoelectronic package 200 is disclosed. The example optoelectronic package 200 can be configured as a TOSA and/or a ROSA.

With particular reference first to FIGS. 3A and 3B, the optoelectronic package 200 includes a leadframe 202 having a plurality of leads 202a-202d extending outward from a casing 204. The casing 204 includes a first portion 204a and a second portion 204b. The second portion 204b of the casing 204 provides mechanical support and electrical isolation for the portions of the leads 202a-202d encased within the second portion 204b. The optoelectronic package 200 also includes an optical port 205 and an optical window 206, both of which are defined in the first portion 204a of the casing 204. The optical port 205 and the optical window 206 may be sized and configured identically to the optical port 105 and the optical window 106, respectively, disclosed above in connection with FIGS. 2A and 2B. The leadframe 202 may also be sized and configured similarly to the leadframe 102 disclosed in connection with FIGS. 2A-2E.

With reference now to FIG. 3C, details regarding the internal components of the optoelectronic package 200 are disclosed. In particular, details regarding the die attach location of an optoelectronic device 218 within the optoelectronic package 200 are disclosed. The leads 202a-202d of the optoelectronic package 200 can be formed as a leadframe 202 from a flat metal tape similar to the tape 101 disclosed in FIG. 2C. However, unlike the optoelectronic package 100, the leads 202a-202d of the optoelectronic package 200 are partially encased by the second portion 204b of the casing 204 prior to the attachment of the optoelectronic device 218 to the lead 202d. This partial enclosing of the leads 202a-202d by the second portion 204b is disclosed in FIG. 3B.

With continuing reference to FIG. 3C, the second portion 204b of the casing 204 includes a first reference indicator 214 and a second reference indicator 216. As disclosed in the example embodiment of FIG. 3C, each reference indicator 214 and 216 is a substantially cylindrical hole formed in the second portion 204b of the casing 204. The reference indicators 214 and 216 may alternatively be implemented with a slightly tapering diameter that decreases from top to bottom in each hole. This slight funnel shape enables instruments to be more easily guided into and released from each hole. As disclosed elsewhere herein, however, each reference indicator 214 and 216 could be another type of hole, a marking, an indentation or other visible indicator, and could have a size and/or geometry different from the size and geometry disclosed in FIG. 3C.

Each reference indicator 214 and 216 is precisely positioned in the second portion 204b of the casing 204 in order to be used as a point of reference when locating a die attach location for the optoelectronic device 218. More particularly, reference indicators 214 and 216 are formed to serve as points of reference for the die attach location of the optoelectronic device 218 disclosed in FIG. 3C, as well as to serve as common points of reference for the attachment location of the first portion 204a of the casing 204 disclosed in FIGS. 3A and 3B. By fixing both the die attach location of the optoelectronic device 218 and the attachment location of the first portion 204a to the same reference indicators 214 and 216, an alignment between, for example, the optical window 206 of the first portion 204a and the optically operative portion of the optoelectronic device 218 can be achieved.

More specifically, the center 215 of the first reference indicator 214 and the center 217 of the second reference indicator 216 can be used to locate the die attach location of the optoelectronic device 218. In particular, the center 215 of the first reference indicator 214 can be used to locate a y-coordinate of the die attach location of the optoelectronic device 218. The center 217 of the second reference indicator 216 can be used to locate an x-coordinate of the die attach location of the optoelectronic device 218. The x-coordinate and the y-coordinate correspond to locations in the x-y coordinate system 250 disclosed in FIG. 3C. The x-axis is parallel to, and the y-axis axis is perpendicular to, the rails (not shown) of the leadframe 202.

In one example alternative embodiment, either the first reference indicator 214 or the second reference indicator 216 can be omitted from the second portion 204b of the casing 204. Where only one of the reference indicators 214 or 216 is present on the second portion 204b of the casing 204, a single reference indicator can be used to precisely locate the die attach location of the optoelectronic device 218.

For example, where the second reference indicator 216 is omitted from second portion 204b of the casing 204, the y-coordinate of the die attach location can be located using the center 215 of the first reference indicator 214, as disclosed above. The x-coordinate of the die attach location can then be located by measuring a predetermined distance 224 to the left of the center 215 along a line (the y-coordinate line) that intersects the center 215 and is parallel to the x-axis of the x-y coordinate system 250. In another example, where the first reference indicator 214 is omitted from the second portion 204b of the casing 204, the x-coordinate of the die attach location can be located using the center 217 of the second reference indicator 216, as disclosed above. The y-coordinate of the die attach location can then be located by measuring a predetermined distance 226 down from the center 215 along a line (the x-coordinate line) that intersects the center 215 and is parallel to the y-axis of the x-y coordinate system 250.

In another example alternative embodiment, the y-coordinate of the die attach location can be located using the center 215 of the first reference indicator 214, as disclosed above. The x-coordinate of the die attach location can then be located by identifying an edge 227 of the lead 202d and measuring a predetermined distance 228 to the right of the edge 227 along a line (the y-coordinate line) that intersects the center 215 and is parallel to the x-axis of the x-y coordinate system 250.

In another example alternative embodiment, the x-coordinate of the die attach location can be located using the center 217 of the second reference indicator 216, as disclosed above. The y-coordinate of the die attach location can then be located by identifying an edge 229 of the lead 202d and measuring a predetermined distance 230 up from the edge 229 along a line (the x-coordinate line) that intersects the center 217 and is parallel to the y-axis of the x-y coordinate system 250.

These four example alternative embodiments illustrate that even a single reference indicator formed in the casing 204 can be useful in locating a die attach location for the optoelectronic device 218. In addition, in another example embodiment, two or more reference indicators in the casing 204 can be used to independently locate a die attach location on the leadframe 202 without reference to the x-y coordinate system 250, as described above in connection with FIG. 2D.

In the example optoelectronic package 200, once the die attach location of the optoelectronic device 118 is located, the optoelectronic device 218 is die attached to the lead 102d. An integrated circuit 231 is also attached to the lead 202b and electrically connected to each of the leads 202a-202d and the optoelectronic device 218 via a plurality of electrical connections 232. The die attachment of the optoelectronic device 218 and the attachment of the integrated circuit 231 can be achieved as described above in connection with the optoelectronic device 118 and the integrated circuit 131. Also, the integrated circuit 231 and the electrical connections 232 may be similar in form and function to the integrated circuit 131 and the electrical connections 132 disclosed in connection with FIG. 2D.

After the optoelectronic device 218 is die attached to the lead 202d, and the integrated circuit 231 is attached to the lead 202b, the first portion 204a of the casing 204 is attached to the second portion 204b of the casing 204, as disclosed in FIGS. 3A and 3B. As noted earlier, the reference indicators 214 and 216 can serve as points of reference for locating the attachment location of the first portion 204a of the casing 204. By fixing both the die attach location of the optoelectronic device 218 and the location of the first portion 204a to a common set of reference indicators 214 and 216, an alignment between, for example, the optical window 206 and the optically operative portion of the optoelectronic device 218 can be achieved.

With reference again to FIGS. 3A and 3B, and with continuing reference to FIG. 3C, once the first portion 204a of the casing 204 is attached to the second portion 204b of the casing 204, the optical window 206 is disposed over the top of the optoelectronic device 218 such that the center 207 of the optical window 206 is substantially aligned with the optically operative portion of the optoelectronic device 218. This alignment allows optical signals to pass between the optoelectronic device 218 and any fiber-optic cable (not shown) that is subsequently connected to the optical port 205. An example of an automated assembly process used to assemble optoelectronic packages, such as the optoelectronic package 200, using one or more reference indicators will be disclosed in greater detail below in connection with FIG. 4.

### IV. Example Assembly Method Using Reference Indicators

With reference now to FIG. 4, an example method 300 for assembling an optoelectronic package is disclosed. In general, the example method 300 uses one or more reference indicators to facilitate the alignment of two or more components as part of a device manufacturing process. For example, the method 300 can use one or more reference indicators to facilitate the alignment of an optoelectronic device with an optical window. The use of one or more reference indicator enables precise automated manufacturing of optoelectronic packages. The various acts of the method 300 can be achieved automatically without human intervention using preconfigured and/or preprogrammed automated assembly equipment. Examples of the various acts of the method 300 will be disclosed below with reference the FIGS. 2D and 3C.

The method 300 includes an act 302 of defining one or more reference indicators in one or more components of an optoelectronic package. For example, the preconfigured automated assembly equipment referred to above can include an instrument capable of punching a substantially circular hole in a metal lead. The instrument can be used by the automated assembly equipment to form the reference indicators 114 and 116 in the metal lead 102d of the leadframe 102, as disclosed in FIG. 2D. Alternatively, the reference indicator can be included in another component of the optoelectronic package, such as the first portion 204b of the casing 204 associated with the optoelectronic package 200, as disclosed in FIG. 3C. In one example embodiment of the act 302, the one or more reference indicators are defined relatively near the die attach location such that the camera can focus simultaneously on both the reference indicators and the die attach location with the camera at maximum magnification. In another example embodiment of the act 302, the one or more reference indicators are defined at a location that corresponds to a known or specified distance from the die attach location.

The method 300 also includes an act 304 of detecting a reference indicator in a component of an optoelectronic package. The act 304 can also include detecting one or more additional reference indicators in one or more components of the optoelectronic package. The detection in either instance may occur during the manufacture of the optoelectronic package.

For example, the preconfigured automated assembly equipment referred to above can include a camera that can be preconfigured with the coordinates of the reference indicator 114 in the x-y coordinate system 150. Although the actual coordinates of the reference indicator 114 may differ from the preconfigured coordinates, due to a slight shift in the location of the lead 102d, for example, the preconfigured coordinates give the automated assembly equipment a general idea of where to look for the reference indicator 114 such that the reference indicator 114 can be located. The automated assembly equipment can also be preconfigured to employ the reference indicator 114 in locating a y-coordinate for the die attach location of the optoelectronic device 118, as disclosed herein. The camera can further be preconfigured with the coordinates of the reference indicator 116 in the x-y coordinate system 250. Although the actual coordinates of the reference indicator 116 may differ from the preconfigured coordinates, due to a slight shift in the location of the lead 102d, for example, the preconfigured coordinates give the automated assembly equipment a general idea of where to look for the reference indicator 116 such that the reference indicator 116 can be located. The automated assembly equipment can also be preconfigured to employ the reference indicator 116 in locating an x-coordinate for the die attach location of the optoelectronic device 118, as disclosed herein. The camera can detect the reference indicators 114 and 116 simultaneously or serially using the preconfigured coordinates of the reference indicators 114 and 116.

The method 300 also includes an act 306 of locating a die attach location for an optoelectronic device using the detected reference indicator(s). The optoelectronic device can be, for example, a surface emitting laser, an edge emitting laser, a light emitting diode, a laser diode, or a photodetector. The die attach location is substantially aligned with a reference indicator along a line that intersects the reference indicator and is parallel to either an x-axis or a y-axis of an x-y coordinate system associated with the optoelectronic package. The die attach location may additionally, or alternatively, be substantially aligned with a second reference indicator along a line that intersects the second reference indicator and is parallel to either the x-axis or the y-axis of the x-y coordinate system associated with the optoelectronic package.

For example, the camera can be used to identify the center 115 of the reference indicator 114. In addition, the camera can be used to identify the center 117 of the second reference indicator 116. In another example, during an automated process of assembling the optoelectronic package 200, a camera can be used to identify the center 215 of the reference indicator 214 disclosed in FIG. 3C. In addition, the camera can be used to identify the center 217 of a second reference indicator 216. In either example, the camera can identify the respective centers of the reference indicators simultaneously or serially. A circular hole, such as the reference indicator 114 or the reference indicator 214, can, in some instances, be more easily detected by a camera than can a straight edge of a lead. It is also a relatively simple calculation for a camera or other device to identify the center of a circle once the circle has been detected by the camera.

Identifying the center of the reference indicator(s) enables a die attach location to be located. For example, once the center 115 of the reference indicator 114 is identified by the camera, the automated assembly equipment can use the center 115 to locate the y-coordinate of the die attach location of the optoelectronic device 118 in the x-y coordinate system 150. The automated assembly equipment may then use the center 117 of the reference indicator 116 to locate the x-coordinate of the die attach location of the optoelectronic device 118 of the x-y coordinate system 150.

Alternatively, the automated assembly equipment may locate the x-coordinate of the die attach location by measuring a predetermined distance 124 to the left of the center 115 along a line (the y-coordinate line) that intersects the y-coordinate and is parallel to the x-axis of the x-y coordinate system 150. In this alternative embodiment, the distance 124 of the die attach location from the center 115 is known at the outset, and the automated assembly equipment uses this distance information to determine where the x-coordinate of the die attach location lies in the context of the leadframe 102.

In another alternative, the automated assembly equipment may locate the x-coordinate of the die attach location by measuring a predetermined distance 128 to the right from an edge 127 along a line (the y-coordinate line) that intersects the center 115 and is parallel to the x-axis of the x-y coordinate system 150.

In any of the above example embodiments, the die attach location can be on the lead in which the reference indicator is included, or on another lead or structure.

The method 300 includes an act 308 of attaching an optoelectronic device to one of the metal leads at the die attach location. For example, the automated assembly equipment can die attach the optoelectronic device 118 to the die attach location located at the x-coordinate and y-coordinate on the lead 102d of the leadframe 102. This die attachment can be achieved, for example, by affixing the optoelectronic device 118 to the lead 102d using epoxy or other suitable adhesive or material.

The method 300 also includes an act 310 of attaching an integrated circuit to one of the metal leads, and an act 312 of electrically connecting the integrated circuit to the optoelectronic device. For example, the automated assembly machinery can attach the integrated circuit 131 to the lead 102b and connect the wire bonds 132 between the integrated circuit 131 and the optoelectronic device 118. In another example, the automated assembly machinery can attach the integrated circuit 231 to the lead 202b and connect the wire bonds 232 between the integrated circuit 231 and the optoelectronic device 218.

The method 300 also includes an act 314 of attaching an optical window over the optoelectronic device such that optical signals can be transmitted to/from the optoelectronic device by way of the optical window. For example, the first portion 104a of the casing 104 can be attached to the leadframe 102 such that the optical window 106 is substantially aligned with the optoelectronic device 118. In another example, the first portion 204a can be attached to the second portion 204b of the casing 204 such that the optical window 106 is substantially aligned with the optoelectronic device 218. In both examples, the portion of casing including the optical window (104a or 204a) is substantially aligned with the reference indicator(s) in a similar fashion as the optoelectronic device (118 or 218) is substantially aligned with the reference indicator(s). By fixing both the die attach location of the optoelectronic device and the attachment location of the casing to the same reference indicators, an alignment between, for example, the optical window and the optically operative portion of the optoelectronic device can be achieved.

The example method 300 therefore uses one or more reference indicators in locating the die attach location of an optoelectronic device and the attachment location of another component, or components, during the assembly of an optoelectronic package. The use of one or more reference indicators enables precise automated alignment between the optoelectronic device and the component(s).

The present invention may be embodied in other specific forms without departing from its spirit. The disclosed embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An optoelectronic package comprising:
a leadframe comprising:
a plurality of metal leads; and
a reference indicator included in one of the metal leads; and
a first component die attached to one of the metal leads at a die attach location, the die attach location being substantially aligned with the reference indicator along a line that intersects the reference indicator and is parallel to either an x-axis or a y-axis of an x-y coordinate system associated with the optoelectronic package.

2. The optoelectronic package as recited in claim 1, further comprising:
a casing at least partially enclosing the leadframe and the optoelectronic device; and
a second component included in the casing, the second component being substantially aligned with the reference indicator along the line that intersects the reference indicator such that the second component is substantially aligned with the first component.

3. The optoelectronic package as recited in claim 2, wherein the first component comprises an optoelectronic device and the second component comprises an optical window.

4. The optoelectronic package as recited in claim 1, wherein the reference indicator is included in the metal lead to which the first component is die attached.

5. The optoelectronic package as recited in claim 1, further comprising a second reference indicator included in one of the metal leads, the die attach location being substantially aligned with the second reference indicator along a line that intersects the second reference indicator and is parallel to either the x-axis or the y-axis of the x-y coordinate system associated with the optoelectronic package.

6. The optoelectronic package as recited in claim 5, wherein the second reference indicator is included in the metal lead to which the first component is die attached.

7. The optoelectronic package as recited in claim 1, wherein the first component comprises a surface emitting laser, an edge emitting laser, a light emitting diode, a laser diode, or a photodetector.

8. The optoelectronic package as recited in claim 1, further comprising an integrated circuit attached to one of the leads, the integrated circuit being in electrical communication with the first component.

9. The optoelectronic package as recited in claim 1, wherein the reference indicator comprises a substantially circular hole defined in the one of the metal leads.

10. The optoelectronic package as recited in claim 1, wherein the die attach location is substantially aligned with the center of the reference indicator along a line that intersects the center of the reference indicator and is parallel to either the x-axis or the y-axis of the x-y coordinate system associated with the optoelectronic package.

11. An automobile comprising:
a fiber-optic network; and
the optoelectronic package as recited in claim 1, the optoelectronic package being in optical communication with the fiber-optic network.

12. An optoelectronic package comprising:
a leadframe comprising a plurality of metal leads;
a first component die attached to one of the metal leads at a die attach location;
a casing at least partially enclosing the leadframe and the first component; and
a reference indicator included in the casing, the die attach location being substantially aligned with the reference indicator along a line that intersects the reference indicator and is parallel to either an x-axis or a y-axis of an x-y coordinate system associated with the optoelectronic package.

13. The optoelectronic package as recited in claim 12, further comprising:
a second component included in the casing, the second component being substantially aligned with the reference indicator along the line that intersects the reference indicator such that the second component is substantially aligned with the first component.

14. The optoelectronic package as recited in claim 13, wherein the first component comprises an optoelectronic device and the second component comprises an optical window.

15. The optoelectronic package as recited in claim 12, further comprising a second reference indicator included in the casing, the die attach location being substantially aligned with the second reference indicator along a line that intersects the second reference indicator and is parallel to either the x-axis or the y-axis of the x-y coordinate system associated with the optoelectronic package.

16. The optoelectronic package as recited in claim 12, wherein the first component comprises a surface emitting laser, an edge emitting laser, a light emitting diode, a laser diode, or a photodetector.

17. The optoelectronic package as recited in claim 12, further comprising an integrated circuit attached to one of the leads, the integrated circuit being in electrical communication with the first component.

18. The optoelectronic package as recited in claim 12, wherein the reference indicator comprises a substantially cylindrical hole defined in the casing.

19. The optoelectronic package as recited in claim 12, wherein the die attach location is substantially aligned with the center of the reference indicator along a line that intersects the center of the reference indicator and is parallel to either the x-axis or the y-axis of the x-y coordinate system associated with the optoelectronic package.

20. An automobile comprising:
a fiber-optic network; and
the optoelectronic package as recited in claim 12, the optoelectronic package being in optical communication with the fiber-optic network.

21. An assembly method comprising:
detecting a reference indicator included in a first component of an optoelectronic package; and
die attaching a second component to the optoelectronic package at a die attach location that is substantially aligned with the reference indicator along a line that intersects the reference indicator and is parallel to either an x-axis or a y-axis of an x-y coordinate system associated with the optoelectronic package.

22. The method as recited in claim 21, further comprising:
attaching a first portion of a casing including an optical window to the optoelectronic package such that the optical window is substantially aligned with the reference indicator along the line that intersects the reference indicator and such that the second component and the optical window are substantially aligned.

23. The method as recited in claim 22, wherein detecting a reference indicator included in a first component of an optoelectronic package comprises detecting a reference indicator defined in a second portion of the casing.

24. The method as recited in claim 21, wherein detecting a reference indicator included in a first component of an optoelectronic package comprises detecting a reference indicator defined in one of a plurality of metal leads.

25. The method as recited in claim 24, wherein die attaching a second component comprises die attaching an optoelectronic device to the metal lead in which the reference indicator is defined.

26. The method as recited in claim 21, wherein the die attach location is further substantially aligned with a second reference indicator included in the first component of the optoelectronic package, the die attach location being substantially aligned with the second reference indicator along a line that intersects the second reference indicator and is parallel to either the x-axis or the y-axis of the x-y coordinate system associated with the optoelectronic package.

27. The method as recited in claim 21, wherein die attaching a second component to the optoelectronic package comprises die attaching a surface emitting laser, an edge emitting laser, a light emitting diode, a laser diode, or a photodetector to the optoelectronic package.

28. The method as recited in claim 21, further comprising:
attaching an integrated circuit to the optoelectronic package; and
electrically connecting the integrated circuit to the optoelectronic device.

29. The method as recited in claim 21, wherein detecting a reference indicator included in a first component of an optoelectronic package comprises detecting a substantially circularly shaped hole defined in the first component of the optoelectronic package.

30. The method as recited in claim 21, wherein the die attach location is substantially aligned with the center of the reference indicator along a line that intersects the center of the reference indicator and is parallel to either the x-axis or the y-axis of the x-y coordinate system associated with the optoelectronic package.

31. The method as recited in claim 21, further comprising:
integrating the optoelectronic package into a fiber-optic network of an automobile
